(19) United States
(12) Patent Application Publication
(10) Pub. No.: US 2023/0146990 A1
(43) Pub. Date: May 11, 2023

(54) MAGNETORESISTANCE SENSOR AND METHOD OF FABRICATION

(71) Applicant: National University of Singapore, Singapore (SG)

(72) Inventors: Junxiong HU, Singapore (SG); Ariando, Singapore (SG); Jun You Tam, Singapore (SG); Gavin Kok Wai Koon, Singapore (SG); Antonio Helio Castro Nato, Singapore (SG)

(21) Appl. No.: 17/907,660

(22) PCT Filed: Mar. 4, 2021
(86) PCT No.: PCT/SG2021/050108

§ 371 Date: Sep. 28, 2022

(30) Foreign Application Priority Data
Mar. 30, 2020 (SG) 10202002964X

(51) Int. Cl. H10N 50/10; H10N 50/01; H10N 50/85

(52) U.S. Cl. CPC H10N 50/10; H10N 50/01; H10N 50/85

(57) ABSTRACT

The present invention relates, in general terms, to magnetoresistance sensors and methods of fabrication thereof. The magnetoresistance sensor comprises a continuous graphene layer disposed on a corrugated and/or stepped surface of a substrate. At least two conductive elements are in contact with the graphene layer. The graphene layer substantially conforms to the corrugated and/or stepped surface of the substrate.

### TECHNICAL FIELD

The present invention relates, in general terms, to magnetoresistance sensors and methods of fabrication thereof.

### BACKGROUND

Magnetoresistance or magnetoresistive (MR) sensors are widely used in day to day applications, where the magnetoresistance value is an important figure of merit. Magnetoresistance sensors are very small components that are designed to sense an applied magnetic field. Because no physical contact or electrical contact is required, the sensor can operate at direct and non-invasive sensing and imaging of magnetic domains across a relatively large air gap. To make embedding possible, magnetoresistance sensors are designed to be small and operate on very little power.

Magnetoresistance is the tendency of a material to change the value of its electrical resistance in an externally-applied magnetic field. The resistance can increase or decrease depending on the orientation of the field lines about the direction of current flow.

There is a wide range of applications for magnetoresistance sensors, most of which revolve around detecting the position or presence of an object. A magnetoresistance sensor can be embedded in a medical cabinet drawer to identify if it is in the open or closed position. A treadmill can use the magnetoresistive sensor as a type of dead-man switch, deactivating the treadmill if the safety key is removed. In information storage applications, data can be retrieved from a magnetic hard disk with a MR read sensor that is extremely sensitive to low (stray) magnetic fields.

Prompted by the huge demand for MR sensors with a high sensitivity, low energy consumption, high temperature operation, low cost and ready availability, researchers have been investigating various methods and suitable materials for making MR sensors.

Current MR sensors in markets tend to be bulky and have a problem of resolving spatial resolution when reduced down to the nanoscale. For traditional 3D material-based giant MR (GMR) or tunnelling MR (TMR) spin-valve sensors, the downsizing will lead to thermal magnetic noise and spin-torque instability, limiting the spatial resolution and sensitivity. Although Superconducting Quantum Interference Device (SQUID) can provide excellent magnetic sensitivity, its utilization has been limited due to its poor spatial resolution and cryogenic operation. On the other hand, while Magnetic Force Microscopy (MFM) and spin-polarized Scanning Tunnelling Microscopy (sp-STM) techniques can provide high spatial resolution, these techniques are invasive due to the use of a magnetic tip.

It would be desirable to overcome or ameliorate at least one of the above-described problems, or at least to provide a useful alternative.

### SUMMARY

The present invention provides a magnetoresistance sensor, comprising:

a) a substrate having a corrugated and/or stepped surface;

b) a continuous graphene layer disposed on the corrugated and/or stepped surface of the substrate; and

c) at least two conductive elements in contact with the graphene layer;

wherein the graphene layer substantially conforms to the corrugated and/or stepped surface of the substrate.

Advantageously, by having the graphene layer conforming to the corrugated and/or stepped surface, a stable magnetoresistance up to about 400 K can be obtained. A magnetoresistance performance of about 2000% with a perpendicular magnetic field of 9.0 T at 300 K and 400 K can also be obtained.

The magnetoresistance sensor is stable and is able to work in wide magnetic field range from at least 10 μT. The corrugated and/or stepped substrate can also serve as a gate dielectric layer, gate voltage can be applied to tune the mobility and carrier density of the graphene layer.

In some embodiments, the corrugated and/or stepped surface of the substrate comprises at least one peak element and one trough element.

In other embodiments, the corrugated and/or stepped surface of the substrate comprises at least two peak elements and two trough elements.

In some embodiments, the corrugated and/or stepped surface of the substrate is selected from staircase structure, square-wave structure, triangle-wave structure, sine-wave structure or a combination thereof.

In some embodiments, the corrugated and/or stepped surface has a peak to peak distance of at least 100 nm.

In some embodiments, the corrugated and/or stepped surface has a trough to trough distance of at least 100 nm.

In some embodiments, an element on the corrugated and/or stepped surface has a height of about 5 nm to about 50 nm.

In some embodiments, the graphene layer is a single mono-atomic layer of graphene.

In some embodiments, the graphene layer is in contact with the corrugated and/or stepped surface of the substrate.

In some embodiments, the at least two conductive elements are independently selected from Cr, Au, Ti, Pd or a combination thereof.

In some embodiments, the at least two conductive elements independently have a thickness of about 2 nm to about 150 nm.

In some embodiments, the substrate is selected from silicon dioxide, silicon nitride, silicon carbide, boron nitride, molybdenum disulfide, molybdenum ditelluride, tungsten diselenide, tungsten disulphide and a complex oxide such as strontium titanate.

The present invention also provides a method of fabricating a magnetoresistance sensor, comprising:

a) forming a corrugated and/or stepped surface on a substrate;

b) disposing a continuous graphene layer on the corrugated surface of the substrate; and

c) contacting at least two conductive elements with the graphene layer;

wherein the graphene layer substantially conforms to the corrugated and/or stepped surface of the substrate.

Advantageously, the method is easily scalable.

In some embodiments, the corrugated and/or stepped surface on the substrate is formed using photolithography and plasma etching, electron beam lithography and plasma etching, or metal mask and plasma etching.

In some embodiments, the graphene layer is disposed on the corrugated and/or stepped surface of the substrate by polymer stamping or chemical vapour deposition (CVD).

### BRIEF DESCRIPTION OF THE DRAWINGS

Embodiments of the present invention will now be described, by way of non-limiting example, with reference to the drawings in which:

FIG. 1 illustrates schematics of different corrugated substrates;

FIG. 2 shows a cross-sectional view of an example sensor, together with an optical micrograph of a top view of the sensor;

FIG. 3 shows an AFM micrograph and height profile graph showing the topography of an exemplary sensor;

FIG. 4 is a plot of magnetoresistance (%) against magnetic field (T) of an exemplary sensor at 300K;

FIG. 5 is a plot of magnetoresistance (%) against magnetic field (T) of the sensor of FIG. 4, at 400K;

FIG. 6 illustrates surface topography characteristics of exemplary sensors and their corresponding magnetoresistance (%) plots;

FIG. 7 illustrates surface topography characteristics of an exemplary sensor with a stepped surface and its corresponding magnetoresistance (%) plot;

FIG. 8 is a schematic illustration of a process of forming electrical contacts on a magnetoresistance sensor;

FIG. 9 illustrates some examples of corrugated surfaces and their corresponding pitches;

FIG. 10 is a flow diagram of an example process for fabricating a magnetoresistance sensor;

FIG. 11 shows three alternative device configurations of a magnetoresistance sensor according to certain embodiments;

FIG. 12 schematically depicts a magnetoresistance sensor deployed as part of a scanning probe magnetometer;

FIG. 13 illustrates an application of a magnetoresistance sensor as a positioning sensor or speedometer;

FIG. 14 illustrates an application of a magnetoresistance sensor in a hearing aid or wireless earbud; and

FIG. 15 illustrates an application of a magnetoresistance sensor in non-destructive crack detection.

### DETAILED DESCRIPTION

The present invention is predicated on the understanding that a single layer of electron conductive material is sufficient for making a magnetoresistance sensor. For example, graphene, a stack of single layer carbon atoms arranged in a hexagonal periodic lattice with weak van der Waals interlayer interaction, can be an electronic material which can exhibit large MR values. Fundamentally, atomically thin structures provide for the simplest system.

In this regard, graphene MR sensors can be used to make 2D magnetic sensors with nanoscale resolution. However, current graphene MR sensors exhibit a weak MR effect in single layer graphene as well as weak MR effect at high carrier density. In this regard, a relatively large MR is only observed when the carrier density is as low as 10¹⁰-10¹¹ cm⁻². The MR of graphene disappears when the carrier density is higher (˜10¹² cm⁻²), as universally obtained in mass produced, industrial-scale graphene. The inventors have found that by providing a corrugated substrate on which graphene can conform, the MR effect can be enhanced up to 5,000%, which is one order of magnitude higher than that reported on previous single-layer graphene devices at the same condition. Further, the MR is demonstrated to be robust against temperature and environmental doping that can induce a high carrier density in graphene. The MR is maintained above 1,000% even at a high-level doping of 10¹² cm⁻².

Accordingly, the present invention provides a magnetoresistance sensor. The magnetoresistance sensor comprises a substrate having a corrugated and/or stepped surface. A graphene layer is disposed on the corrugated surface of the substrate. The graphene layer is preferentially a single layer of graphene. Because of the flexibility of graphene, single-layer graphene stacked on a terraced substrate will replicate a similar terrace morphology as the substrate. This graphene layer can be a continuous graphene layer, and in this regard, the graphene layer is unbroken and substantially covers the corrugated surface. At least two conductive elements are in contact with the graphene layer. The two conductive elements are spaced apart from each other. The graphene layer is substantially conformed to the corrugated surface of the substrate. In this regard, the graphene layer adopts a corrugated graphene structure.

As used herein, the graphene layer is a two-dimensional (2D) material. A 2D material is also referred to as a single-layer material, consisting of a single layer of atoms. Graphene is an allotrope of carbon consisting of a single layer of atoms arranged in a two-dimensional honeycomb lattice.

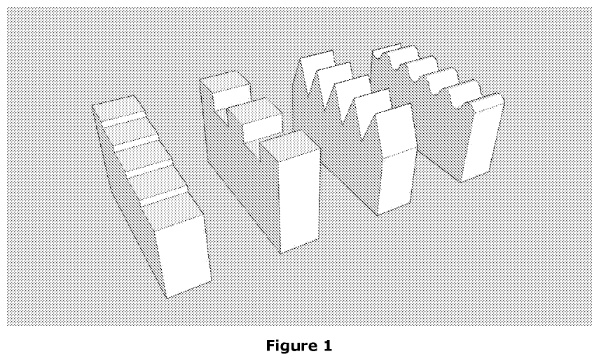

FIG. 1 illustrates schematics of different corrugated surfaces showing from left to right the staircase structure, square-wave structure, triangle-wave structure and sine-wave profile. The corrugated substrate can also be periodically spaced square structures, triangle structures and bubble-type structures. The corrugated and/or stepped surface can be a combination of the above mentioned structures or profiles.

“Corrugated” and “stepped” as used herein refers to the ordered patterning of a surface in 1D and/or 2D. The corrugation can for example be a series of parallel ridges and grooves, while stepped can for example be a series of parallel ridges or grooves. The parallel ridges and/or grooves can further be alternating. This is in contrast to a randomly roughened or uneven surface which can be formed for example by sanding. The corrugated surface of the substrate can comprise at least one peak element and one trough element. Alternatively, the corrugated surface of the substrate can comprise at least two peak elements and at least two trough elements. The corrugated surface can have a peak to peak distance of at least 100 nm. In other embodiments, the peak to peak distance is at least 50 nm, at least 150 nm, at least 200 nm, at least 250 nm, or at least 300 nm. The corrugated surface can have a trough to trough distance of at least 100 nm. In other embodiments, the trough to trough distance is at least 50 nm, at least 150 nm, at least 200 nm, at least 250 nm, or at least 300 nm. Alternatively, the elements on the corrugated surface can be separated by a pitch of at least 100 nm. In other embodiments, the pitch is at least 50 nm, at least 150 nm, at least 200 nm, at least 250 nm, or at least 300 nm.

The surface can alternatively be a stepped surface. The stepped surface can comprise at least one peak element and one trough element. The peak element can be a first step and the trough element can be a second step positioned lower than the first step. The stepped surface can have a peak to trough distance of at least 100 nm. Alternatively, the elements on the corrugated surface can be separated by a pitch of at least 100 nm. In other embodiments, the pitch is at least 50 nm, at least 150 nm, at least 200 nm, at least 250 nm, or at least 300 nm.

As used herein, ‘pitch’ is associated with, and thus quantified as, frequency. In this regard, the pitch quantifies how far apart the elements are on the surface.

FIG. 9 shows some examples of the corrugated surfaces and their corresponding pitches.

An element on the corrugated surface can have a height of about 5 nm to about 50 nm. The height can be relative to another element on the surface. For example, a height of a peak element relative to a trough element can be of about 5 nm to about 50 nm. If a stepped structure is used, the height of a step can be relative its adjacent step. Alternatively, the height of the element can be relative from a plane equidistance from a peak element and a trough element. In other embodiments, the height is about 10 nm to about 50 nm, about 15 nm to about 50 nm, about 20 nm to about 50 nm, about 25 nm to about 50 nm, about 30 nm to about 50 nm, or about 40 nm to about 50 nm. In other embodiments, the height is at least 5 nm, at least 15 nm, at least 20 nm, at least 25 nm, at least 30 nm, at least 35 nm, at least 40 nm, at least 45 nm, or at least 50 nm.

The inventors have found that a corrugated surface can be further advantageous when compared to a lattice structure (i.e. open-celled structures composed of one or more repeating unit cells). In comparison, a lattice structure can only increase the MR effect of graphene by a factor of 3. Further, this method of using lattice structures is not commercially viable due to the difficulty in mass producing graphene/lattice hetero-structure. Moreover, the lattice structure cannot be designed and controlled easily. The corrugated surface is also further advantageous to a random surface roughness. Such a surface is difficult to control, and in this regard, a good control on its MR cannot be obtained for use in a typical magneto-resistive sensor; i.e. sensitivity is essential and crucial. It is important to have good stability and reproducibility in such devices.

Accordingly, in some embodiments, the substrate has a corrugated and/or stepped surface. In this regard, the corrugated and/or stepped surface is formed as a 2D array extending in an X and Y direction. This is advantageous as a large surface area can improve the direct and non-invasive sensing and imaging of magnetic domains. In some embodiments, the substrate has a stripped corrugated and/or stepped surface. In this regard, the ‘stripped’ surface comprises a single row or column of elements (1D array); i.e. the elements are not arranged in a 2D array or lattice. This is further advantageous as it allows for good control over the surface/geometry to meet the stringent requirements of magneto-resistive sensor.

The substrate can be silicon dioxide, silicon nitride, silicon carbide, boron nitride, molybdenum disulfide, tungsten diselenide, other stable 2D materials and thin film semiconductors. As the name suggests, the layer serves as a substrate for graphene layer to conform onto, thus creating the final corrugated structure.

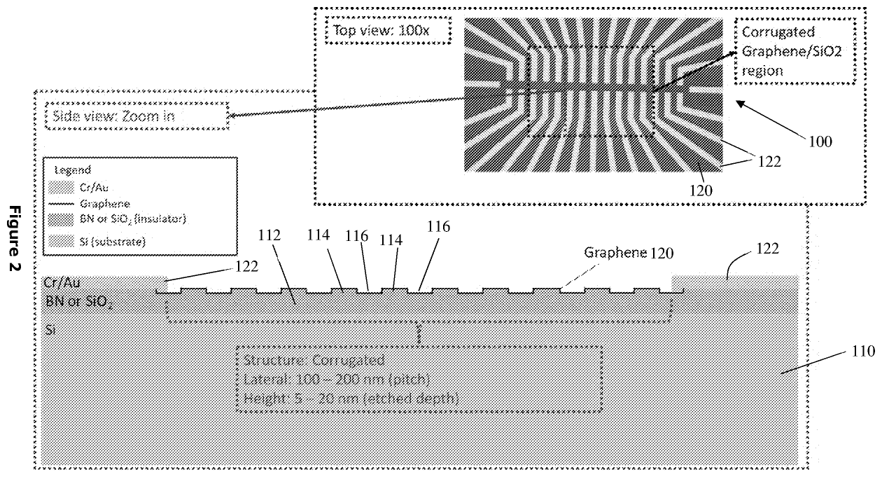

FIG. 2 illustrates, at the top, an optical micrograph of the top of an exemplary sensor 100. A schematic cross-sectional view of the sensor 100 is shown at the bottom of the Figure. The sensor 100 comprises a silicon substrate 110 on which a corrugated insulating layer 112 of silicon oxide or boron nitride is formed. The corrugated layer 112 has a surface structure comprising a plurality of lands 114 and grooves 116 that are interleaved with each other. A graphene layer 120 is formed on, and conforms to, the corrugated structure. In this case the corrugated structure is formed with a periodically etched square-wave profile. Conductive elements in the form of electrical contact pads 122 are applied to the insulating layer in a manner such that they also at least partially contact the graphene layer 120. The conductive elements may be made of Cr and Au metal layers with thickness 5 and 65 nm respectively. As can be seen, the graphene layer 120 forms a continuous layer on the corrugated surface of the insulating layer 112. In this regard, one part of the graphene layer is in contact with a first conductive element of the conductive elements 122, and another part of the graphene layer is in contact with a second conductive element of the conductive elements 122.

It will be appreciated that the sensor 100 of FIG. 2 may be packaged in any suitable manner, as known in the art. For example, one or more sensors 100 may be adhered to a lead frame, and the contact pads 122 may be connected with lead frame terminals via wire bonding. The lead frame may then be encapsulated in plastic with the lead frame terminals providing the means for the sensor(s) 100 to be connected to external circuitry for readout and/or programming.

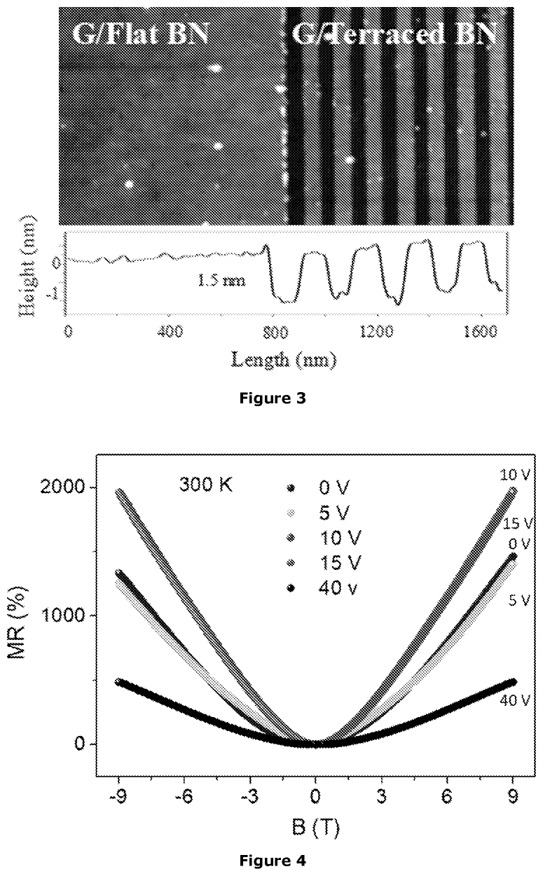

FIG. 3 illustrates topographic features of an exemplary sensor. The AFM micrographs at top show the topography of a 1-layer graphene sensor on flat boron nitride and corrugated boron nitride substrates. In this example, the substrate is boron nitride with etched depth of 1.5 nm and pitch of 100 nm.

As mentioned, the corrugated graphene structure is made by disposing at least a single layer of graphene on a corrugated substrate. Accordingly, in some embodiments, the graphene layer is in contact with the corrugated and/or stepped surface of the substrate. This allows the graphene layer which is flexible and not rigid to conform to the corrugated and/or stepped surface. In some embodiments, the graphene layer is a single mono-atomic layer of graphene.

Advantageously, having the graphene layer conform to the corrugated surface enhances the MR effect.

Magnetic element is the element which responses to external magnetic field giving rise to the MR effect. While there are other known ways to increase the magnetoresistance of graphene such as by placing graphene on boron nitride, these methods are not commercially viable due to the difficulty in mass producing this hetero-structure. The present invention is based on increasing magnetoresistance in graphene by utilising the disorder-induced MR effect, which can be described by the random resistor network model and/or the self-consistent effective medium theory. These two theories have been calculated to be mathematically equivalent. In this regard, the physical origin of the large MR in graphene is due to the presence of electron-hole puddles induced by carrier inhomogeneity. In the presence of a magnetic field, the electrons will not travel in a straight line, but is strongly distorted by discontinuities at the boundary of puddles, thereby enhancing the scattering. Accordingly, by making use of the corrugated and/or stepped surface to induce charge disorder in graphene, a large MR can be obtained.

This is in contrast to magnetic moments caused by spin orientation. For example, in TMR, two ferromagnetic layers are separated by an insulator thin layer, electrical resistance of the multilayer in the perpendicular direction to the film changes depending on the orientations of the magnetizations of ferromagnetic thin layers because of spin dependent electron tunnelling between the two ferromagnetic layers. When the directions of the magnetizations of the two ferromagnetic electrodes are the same, the possibility of electron tunnelling between the two ferromagnetic electrodes through the insulator layer becomes larger, resulting in larger tunnelling current.

Further advantageously, this corrugated/stepped structure can be artificially designed and controlled, which is compatible with current CMOS technology. The at least two conductive elements can be independently selected from Cr, Au, Ti, Pd or a combination thereof. For example, one combination of the conductive element can be a 5 nm layer of Cr overlaid with a 45 nm layer of Au, or with a 65 nm layer of Au. Another combination is a 2 nm layer of Cr or Ti overlaid with a 100 nm of Au or Ag. In this regard, a conductive element can be made up of 2 or more layers of metals in contact with each other. These elements are conductive in the sense that they have the property of being able to conduct electricity to or away from the graphene layer, thus acting as electrical contacts for connecting the sensor to an external circuit. This allows a signal/output to be recorded.

In some embodiments, the at least two conductive elements independently have a thickness of about 2 nm to about 150 nm. In other embodiments, the thickness is about 2 nm to about 120 nm, about 5 nm to about 100 nm, about 10 nm to about 100 nm, about 20 nm to about 100 nm, about 30 nm to about 100 nm, about 40 nm to about 100 nm, about 50 nm to about 100 nm, about 60 nm to about 100 nm, or about 70 nm to about 100 nm.

The conductive element (electrode) placement affects the electrical resistance R measured. As the magnetoresistance MR value is defined as (ΔR*100/R) %, R changes (ΔR) upon the application of an external magnetic field B thus the MR is a function of B. The placement of the electrodes can affect the spatial resolution of the sensor and the MR.

In some embodiments, the electrodes are spaced apart by at least about 1 μm. In other embodiments, the spacing is at least about 1.5 μm, about 2 μm, about 4 μm, about 5 μm, about 7 μm, or about 10 μm.

An example of the magnetoresistance obtainable from the sensor of embodiments of the present invention is shown in FIG. 4. FIG. 4 illustrates a plot of magnetoresistance MR % of a sensor based on 1-layer graphene on a terraced boron nitride substrate as a function of the external magnetic field with different applied gate voltages. These measurements were performed at room temperature 300K.

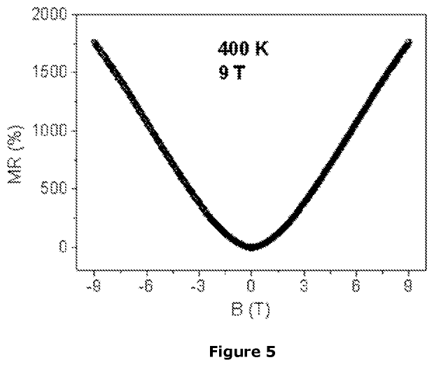

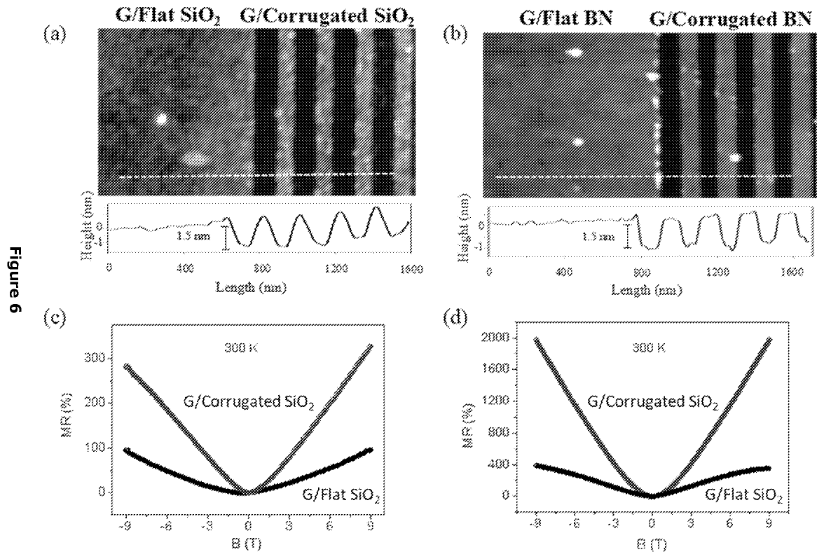

As another example, FIG. 5 illustrates magnetoresistance (%) against magnetic field (T) of a sensor based on 1-layer graphene on a terraced boron nitride substrate as a function of the external magnetic field with 15 V gate voltage applied. This measurement was performed at an elevated temperature of 400K.

The performance of the magnetoresistance sensors is improved with the use of corrugated substrates. As an example, FIG. 6 illustrates (a) AFM image of single-layer graphene on flat SIO₂ and corrugated SiO₂, and (b) AFM image of single-layer graphene on flat BN and corrugated BN. Magnetoresistance MR % of graphene on a flat and terraced SiO₂ substrate as a function of the external magnetic field at 300 K is shown in FIG. 6c. The lower black line is the MR of graphene on flat SiO₂ and the upper red line is the MR of graphene on corrugated SiO₂. The magnetoresistance MR % of graphene on a flat and terraced BN substrate as a function of the external magnetic field at 300 K is shown in FIG. 6d. The lower black line is the MR of graphene on flat BN and the upper red line is the MR of graphene on corrugated BN.

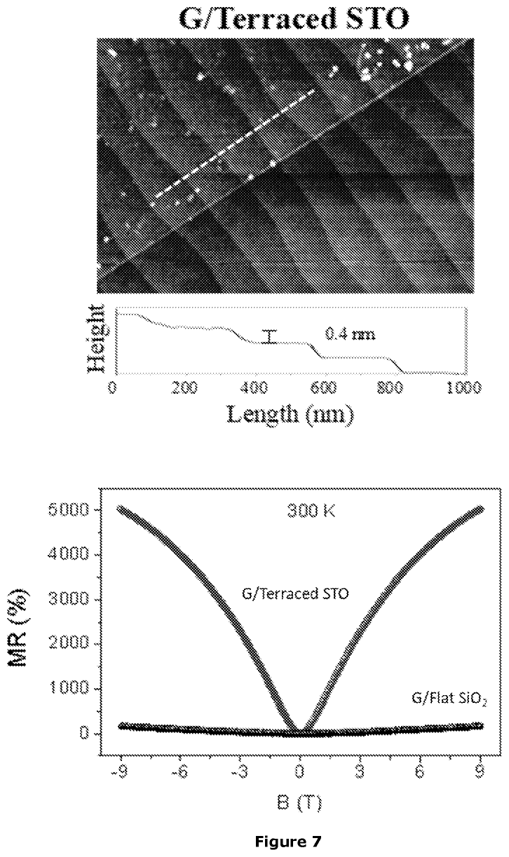

FIG. 7 illustrates an AFM image of an exemplary sensor with a stepped surface and its corresponding magnetoresistance (%) plot.

A magnetoresistance ratio of the corrugated graphene structure is determined by a difference in longitudinal resistance of the graphene layer with and without an applied perpendicular magnetic field. The ratio is given as (ΔR*100/R) %, wherein R is the resistivity of a material in magnetic field of a magnitude of zero, and ΔR is the resistivity in a magnetic field of a certain magnitude. (ΔR/R) depends on the magnetic field B, i.e. its magnitude and direction as well.

The sensor of embodiments of the present invention can have a magnetoresistance ratio of about 250% to about 6000%. In other embodiments, magnetoresistance ratio is of about 260% to about 5900%, about 270% to about 5800%, about 280% to about 5700%, about 290% to about 5600%, or about 300% to about 5500%.

An example of the magnetoresistance ratio of a magnetoresistance sensor of embodiments of the present invention is given in the table below:

| | G on Flat | G on terraced | G on flat | G on terraced |
|---|---|---|---|---|
| T | SiO₂ | SiO₂ | BN | BN |
| 300 K | 100% | 300% | 400% | 2000% |
| 400 K | 180% | 380% | 600% | 1600% |

In other examples, it is shown that by conforming the graphene layer to a corrugated surface the MR effect can be enhanced up to 5,000%. The MR is shown herein to be robust against temperature and environmental doping that might induce a high carrier density in graphene. The MR performance is good, being maintained above 1,000% even at a high-level doping of 10¹² cm⁻². For example, up to about 2000% can be maintained with a perpendicular magnetic field of 9.0 T at 300 K, and up to about 1750% can be maintained with a perpendicular magnetic field of 9.0 T at 400 K. Further, the sensors have a high temperature operation stability, showing high and stable magnetoresistance at about 400 K, which is a typical sensor operation temperature. The sensors have a wide magnetic field range detection, and are able to work in wide magnetic field range from 10 μT to no measurable upper limit.

In this regard, the sensor of embodiments of the present invention can have a MR effect of at least 1000% in the presence of a magnetic field of 9.0 T. The sensor can have a MR effect in the presence of a magnetic field of at least 10 μT.

Such sensors are highly applicable in hearing aids and can act as a replacement sensor for TMR. These sensors can also be used to increase the spatial resolution and sensitivity in scanning probe magnetometry and biosensors.

A further problem in the art relates to the fabrication of such sensors. For example, graphene is known to be able to grow in large scale in corrugated SiC substrate but this growth method is not preferred due to the fact that the resultant graphene formed surface is uneven. In fact, the uneven surface results in many defects such that a good MR is not obtainable. In this regard, embodiments of the present invention provide a method of fabrication which reduces the complexity of fabrication of the previous graphene MR sensors by eliminating the need of transferring graphene onto substrate.

Accordingly, the sensors of embodiments of the present invention can be easily customizable to suit the application needs and can be easily scaled for sensor manufacturing.

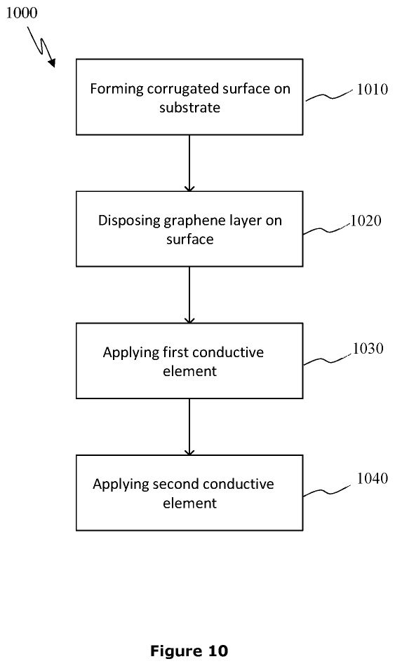

As shown in FIG. 10, an example method of fabricating a magnetoresistance sensor comprises:

a) forming 1010 a corrugated and/or stepped surface on a substrate;

b) disposing 1020 a continuous graphene layer on the corrugated surface of the substrate; and

c) applying (1030, 1040) at least two conductive elements with the graphene layer;

wherein the graphene layer substantially conforms to the corrugated and/or stepped surface of the substrate.

In other embodiments, at least a first conductive element is applied with a side of the graphene layer. A second conductive element is subsequently or simultaneously applied with a side of the graphene layer. In other embodiments, the first and second conductive elements are applied by contacting with the graphene layer. In this regard, the conductive elements can be pre-formed and pressed against the graphene layer so as to be contacted with the graphene layer.

In some embodiments, the corrugated surface on the substrate is formed using photolithography and plasma etching. Photolithography is a patterning process in which a photosensitive polymer is selectively exposed to light through a mask, leaving a latent image in the polymer that can then be selectively dissolved to provide patterned access to an underlying substrate. The photolithography resolution is about 600 to about 800 nm. Plasma etching is a form of plasma processing and involves a high-speed stream of glow discharge (plasma) of an appropriate gas mixture being shot (in pulses) at a sample. The plasma source, known as etch species, can be either charged (ions) or neutral (atoms and radicals). Depending on the method used, various masks can be used for forming the corrugated surface. The skilled person would also understand that other lithographically-patterned lattice deformation can be used.

For example, the corrugated surface can also be created via a two-step process of electron beam lithography and plasma etching. Electron-beam lithography is the practice of scanning a focused beam of electrons to draw custom shapes on a surface covered with an electron-sensitive film called a resist (exposing). The electron beam changes the solubility of the resist, enabling selective removal of either the exposed or non-exposed regions of the resist by immersing it in a solvent (developing). The purpose, as with photolithography, is to create very small structures in the resist that can subsequently be transferred to the substrate material, often by etching. The electron beam lithography resolution is about 10 to about 20 nm.

Alternatively, a hard metal mask and plasma etching may be used. In this regard, a mask is created on a metal such as Cr, Ti or Al, from which structures can be formed on a substrate using plasma etching.

In some embodiments, the graphene layer is disposed on the corrugated surface of the substrate by polymer stamping or by chemical vapour deposition (CVD). For example, in polymer stamping, a viscoelastic gel or transparent polymer is used as a support layer for the graphene layer. The graphene layer can be exfoliated onto the polymer directly or picked up from other substrates like silicon dioxide. Finally, the gel or polymer is peeled off slowly from the corrugated surface of the substrates, and this allows the flakes to adhere to the substrate. Such viscoelastic gels and transparent polymers include PDMS, polycarbonate (PC) and polymethyl methacrylate (PMMA). Polymer stamping methods are disclosed in, for example, A. Castellanos-Gomez et al., “Deterministic transfer of two-dimensional materials by all-dry viscoelastic stamping”; 2D Materials; Volume 1 Number 1 (2014), F. Pizzocchero, et al., “The hot pick-up technique for batch assembly of van der waals heterostructures”; Nature Communication 7, 11894 (2016), and C.R. Dean et al., “Boron Nitride substrates for high quality graphene electronics; Nature Nanotechnology 5, 722-726(2010)”, each of which are incorporated by reference. The skilled person would also understand that other graphene transfer methods can be used.

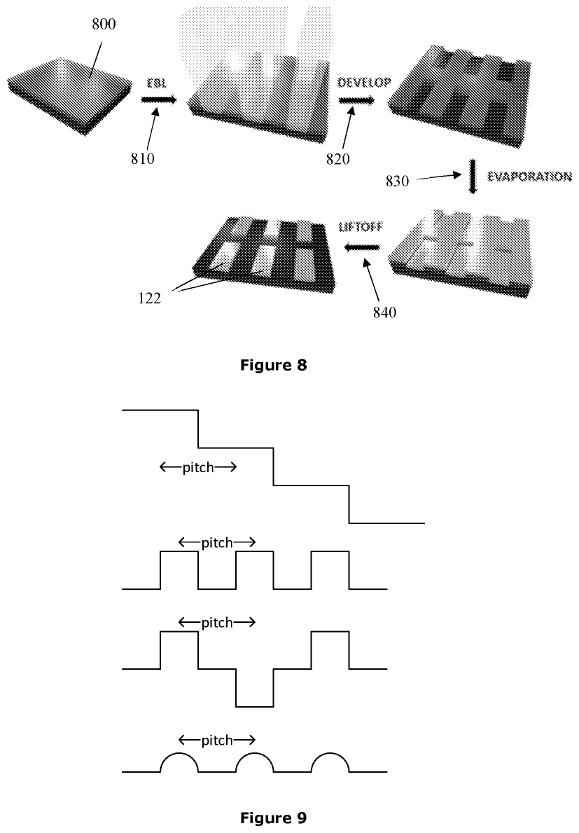

FIG. 8 shows how the conductive elements can be applied to the graphene. In a first operation 800, the substrate is spin-coated with a resist. This may be an electron beam resist (for example, PMMA or ZEP) in the case of electron beam lithography, and photoresist (for example, S1805 or AZ1512) in the case of photolithography. In a subsequent operation 810, the resist can be irradiated in the desired pattern (or the inverse of the desired pattern, depending on whether the resist is a positive resist) by an electron or photon beam. Next, at 820, a development (wash off) process may be carried out. This removes the exposed (for a positive resist) or unexposed (for a negative resist) areas of the resist.

After lithography and development, the sample is subjected to metal deposition 830 in a thermal evaporator or electron beam evaporator. To form the electrical contacts 122, successive layers of chromium and gold, with thickness 5 nm and 65 nm respectively, may be deposited.

Finally, at 840, the sample may undergo a liftoff process (for example, in acetone) and an IPA rinse before being blow-dried.

Embodiments of the present invention may produce physical MR based on a standard Hall bar structure. The physical MR results from the orbital motion of the charge carriers caused by the Lorentz force. The skilled person would understand that this physical MR can also be combined with other device configurations, for example, geometric MR. The geometric MR depends strongly on the boundary conditions for current flow. To further boost the MR sensitivity, other kinds of device configurations such as Van der Pauw structure, disk structure and extraordinary magnetoresistance (EMR) structure can be used, and are included within the scope of this invention.

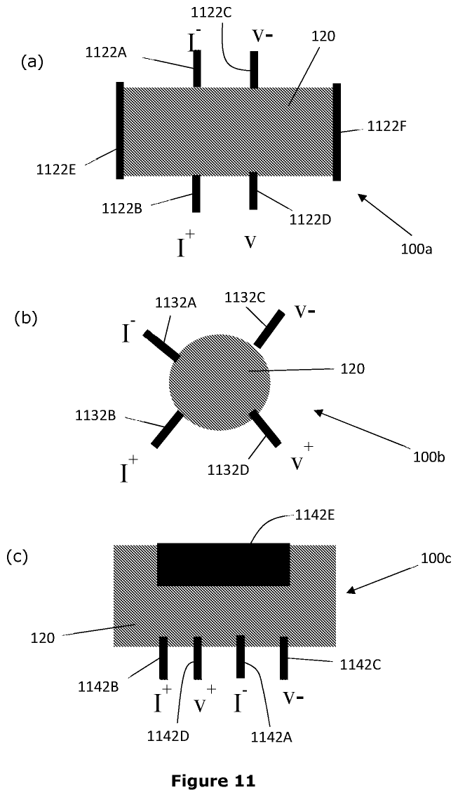

For example, FIG. 11(a) shows a schematic of a sensor 100a having a van der Pauw structure. The sensor 100a comprises a corrugated and/or stepped graphene surface structure 120, which may be formed on a substrate (not shown) in like fashion to the sensor 100 of FIG. 2. The sensor 100a is of generally rectangular shape as viewed from above. A plurality of electrical contacts 1122A to 1122F are provided in contact with the graphene surface structure 120. For example, a first pair of contacts 1122E and 1122F may be provided on first opposed sides of the surface structure 120 for passage of a DC current I that is injected into contact 1122E and flows out of contact 1122F (or vice versa). One or more second pairs of contacts 1122A and 11228, or 1122C and 1122D, may be provided on second opposed sides of the surface structure 120 (that are orthogonal to the first opposed sides, for example) for measurement of a dropped voltage V across the contacts 1122A and 11228, or 1122C and 1122D.

In another example as shown in FIG. 11(b), a sensor 100b may be of generally circular or disc shape. The sensor 100b comprises a corrugated and/or stepped graphene surface structure 120. A plurality of electrical contacts 1132A to 1132D are provided in contact with the graphene surface structure 120. For example, a first pair of contacts 1132A and 11328 may be provided on a first side of the sensor 100b for passage of a DC current I that is injected into contact 1132A and flows out of contact 11328 (or vice versa). A second pair of contacts 1132C and 1132D may be provided on a second side of the sensor 100b opposed to the first side for measurement of a voltage V across the contacts 1132C and 1132D.

In a further example as shown in FIG. 11(c), a sensor 100c may be of generally rectangular shape. The sensor 100c comprises a corrugated and/or stepped graphene surface structure 120. A plurality of electrical contacts 1142A to 1142E are provided in contact with the graphene surface structure 120. For example, a first pair of contacts 1142A and 1142B may be provided on a first side of the sensor 100c for passage of a DC current I that is injected into contact 1142A and flows out of contact 1142B (or vice versa). A second pair of contacts 1142C and 1142D may be provided on the first side of the sensor 100c and in interleaved relationship with contacts 1142.1 and 1142.2 for measurement of a voltage V across the contacts 1142.3 and 1142.4. A further contact 1142E may be provided for enhancing the signal measured across 1142C and 1142.D.

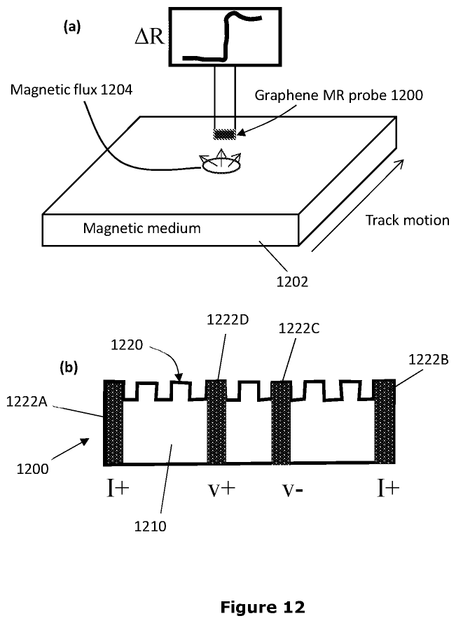

The MR sensor of embodiments of the present invention can be used to detect nanoscale magnetic domains, and can be used in scanning probe magnetometry, biosensing, and magnetic storage, for example. A schematic depiction of an example MR sensor 1200 as used in scanning probe magnetometry is shown in FIGS. 12(a) and 12(b). The sensor 1200 may have a similar configuration to the sensor 100 of FIG. 2, and in this regard, and with reference to FIG. 12(b), may comprise a substrate 1210 having a corrugated surface structure on which a graphene layer 1220 is disposed, such that the graphene layer 1220 conforms to the shape of the underlying surface structure. The sensor 1200 may further comprise a plurality of electrical contacts 1222A to 1222D that are in contact with the graphene layer 1220. Contacts 1222A and 1222B may be located at opposite ends of the sensor 1200, while contacts 1222C and 1222D are located intermediate the contacts 1222A and 1222B. A DC current I may be injected at contact 1222A and flow out of contact 1222B (or vice versa), and a DC voltage V may be measured across contacts 1222C and 1222D. A graphene MR probe comprising the sensor 1200 may be scanned across the surface of a magnetic medium 1202, such that when a magnetic domain 1204 is encountered by the probe, an abrupt change in resistance is measured (as seen in the inset of FIG. 12(a)).

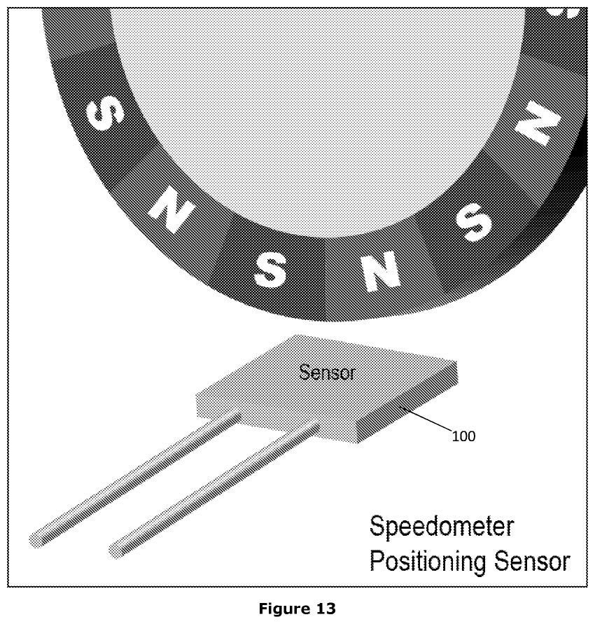

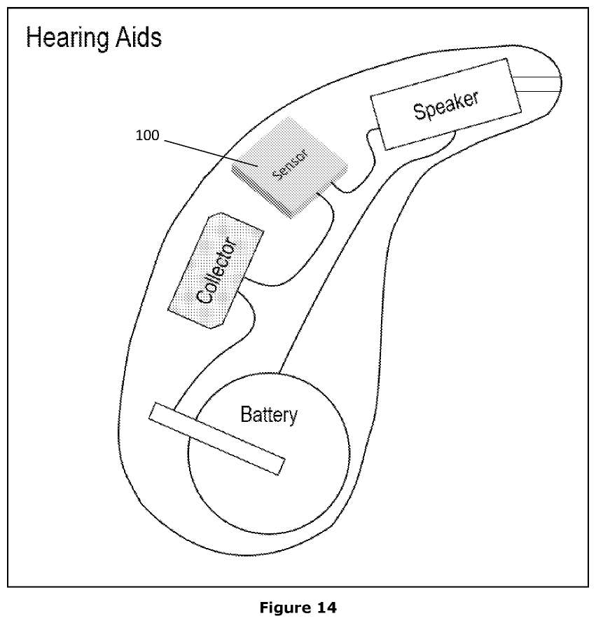

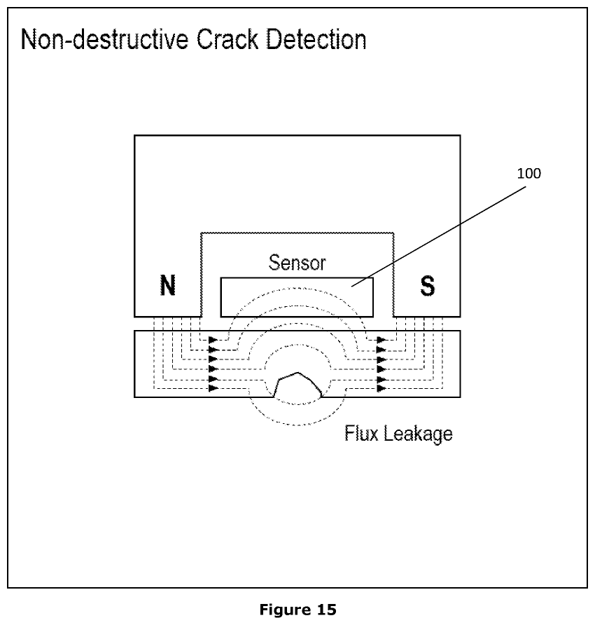

The MR sensor of embodiments of the present invention can also be used in various other applications. For example, a MR sensor such as the sensor 100 (or alternative sensors 100a, 100b, 100c, or 1200), can be used as a positioning sensor 100 of a speedometer (FIG. 13), in a hearing aid or wireless earbud (FIG. 14), or in non-destructive crack detection (FIG. 15).

### EXAMPLES

Substrate Preparation

Etch mask patterning via lithography and plasma etching: The substrate is spin-coated with electron beam resist (for eg. PMMA, ZEP) in the case of electron beam lithography and photo resist (for eg. S1805, AZ1512) in the case of photo lithography. The etch mask can be fabricated by irradiating by electron or photo beam and development (wash off) processing of the irradiated/unwanted areas for the case of positive resists. For negative resists (HSQ, SU-8), the irradiated areas will stay after the development process. Next, the whole assembly is subjected to plasma etching to remove controllably the substrate layer underneath the exposed areas. Finally, the resist is washed off, leaving the corrugated substrate layer.

Hard metal mask and plasma etching: With the hard metal mask, there is no need to fabricate the etch mask via a lithography process. The mask can be placed on top of the substrate and the whole assembly is subjected to plasma etching to remove the exposed substrate layer. The mask acts as the protection layer, as opposed to resists in the previous case.

Graphene Transfer

Dry transfer via polymer layer: Graphene layer(s) can be prepared by peeling off from HOPG graphite crystals and deposited onto an intermediate substrate. Next, the graphene layer(s) can be aligned and placed onto the corrugated substrate via PDMS stamping. PDMS is a transparent polymer layer that can be used to stamp and “pick-up” graphene layer(s) and to release graphene layer(s) onto a designated substrate upon heating.

Wet transfer of CVD graphene: With the advancement of CVD techniques, large area of graphene layer(s) can be easily grown on Cu and transferred via wet etching transfer. The transfer of the CVD-derived graphene films to a nonspecific substrate can be enabled by the wet-etching of the underlying Cu/Ni film (depending on which film the Graphene is grown on). This is carried out by treating the film with an aqueous HCl (for the case of Ni) or ammonium persulphate (APS) (for the case of Cu) solution after a support material is coated on the Ni/graphene or Cu/graphene surface, or in particular a poly[methyl methacrylate] (PMMA) layer. This results in a free-standing PMMA/graphene membrane that can be handled easily and placed on the desired target substrate (graphene facing the surface). Finally, the PMMA can be dissolved with acetone to yield a graphene film on the desired substrate. An exemplary reference which discloses the wet transfer technique is Reina, A. et al. Large area, few-layer graphene films on arbitrary substrates by chemical vapor deposition; Nano Lett. 9, 30-35 (2009), which is incorporated by reference herein.

Electrical Contact

Patterning via photolithography or electron beam lithography: As shown in FIG. 8, the substrate can be spin-coated with an electron beam resist (for example PMMA, ZEP) in the case of electron beam lithography and photo resist (for example S1805, AZ1512) in the case of photolithography. The electrical contacts can be fabricated by irradiating by electron/photo beam and development (wash off) process of the unwanted areas for the case of positive resists. For negative resists (HSQ, SU-8), the irradiated areas will stay after the development process.

Metal deposition via thermal evaporation or electron beam evaporation or sputtering: After lithography and development, the sample can be subjected to metal deposition in a thermal evaporator or electron beam evaporator or sputterer. To form the electrical contacts, 1) chromium Cr and 2) gold Au are deposited with thickness 5 nm and 65 nm respectively.

Liftoff in acetone: Finally, the sample undergoes a liftoff process in acetone and an IPA rinse before being blow-dried.

Measurement

Electrical transport measurements were carried out in a physical property measurement system (PPMS) interfaced with a source meter (Model 2400, Keithley Inc.) and a multimeter (Model 2002, Keithley Inc.). Following are the key measurement parameters:

Excitation current I passing through source—drain contacts (contacts on the opposite ends): A direct current in the range of 100 nA to 1 μA can be applied through the sample to measure the longitudinal resistance with and without magnetic field (perpendicular to the sample plane) with magnitude ranging from −9 to 9 T.

Differential voltage ΔV measured through longitudinal contacts: A differential voltage can be measured with adjacent pair of electrodes on the same side with magnitude ranging from 0.1 to 10 mV for an excitation current of 1 μA.

Longitudinal resistance R: The longitudinal resistance with and without magnetic field can be calculated from R=ΔV/I and can be plotted as a function of applied magnetic field. See FIG. 4 and FIG. 5 below.

Magnetoresistance MR %:

The magnetoresistance of the sensor is defined as the percentage change of the longitudinal resistance upon the application of a perpendicular magnetic field. The reference resistance would be the longitudinal resistance without magnetic field. The magnetoresistance can be calculated via MR %=ΔR/R(B=0).

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A magnetoresistance sensor, comprising:
a) a substrate having a corrugated and/or stepped surface;
b) a continuous graphene layer disposed on the corrugated and/or stepped surface of the substrate; and
c) at least two conductive elements in contact with the graphene layer
wherein the graphene layer substantially conforms to the corrugated and/or stepped surface of the substrate.

2. The magnetoresistance sensor according to claim 1, wherein the corrugated and/or stepped surface of the substrate comprises at least one peak element and one trough element.

3. The magnetoresistance sensor according to claim 1, wherein the corrugated and/or stepped surface of the substrate comprises at least two peak elements and two trough elements.

4. The magnetoresistance sensor according to claim 3, wherein the corrugated and/or stepped surface of the substrate is selected from staircase structure, square-wave structure, triangle-wave structure, sine-wave structure and a combination thereof.

5. The magnetoresistance sensor according to claim 3, wherein the corrugated and/or stepped surface has a peak to peak distance of at least 100 nm.

6. The magnetoresistance sensor according to claim 1, wherein the corrugated and/or stepped surface has a trough to trough distance of at least 100 nm.

7. The magnetoresistance sensor according to claim 1, wherein an element on the corrugated and/or stepped surface has a height of about 5 nm to about 50 nm.

8. The magnetoresistance sensor according to claim 1, wherein the graphene layer is a single mono-atomic layer of graphene.

9. The magnetoresistance sensor according to claim 1, wherein the graphene layer is in contact with the corrugated and/or stepped surface of the substrate.

10. The magnetoresistance sensor according to claim 1, wherein the at least two conductive elements are independently selected from Cr, Au, Ti, Pd or a combination thereof.

11. The magnetoresistance sensor according to claim 1, wherein the at least two conductive elements independently have a thickness of about 2 nm to about 150 nm.

12. The magnetoresistance sensor according to claim 1, wherein the substrate is selected from silicon dioxide, silicon nitride, silicon carbide, boron nitride, molybdenum disulfide, molybdenum ditelluride, tungsten diselenide, tungsten disulphide and a complex oxide such as strontium titanate.

13. A method of fabricating a magnetoresistance sensor, comprising:
a) forming a corrugated and/or stepped surface on a substrate;
b) disposing a continuous graphene layer on the corrugated and/or stepped surface of the substrate; and
c) contacting at least two conductive elements with the graphene layer,
wherein the graphene layer substantially conforms to the corrugated and/or stepped surface of the substrate.

14. The method according to claim 13, wherein the corrugated and/or stepped surface on the substrate is formed using photolithography and plasma etching, electron beam lithography and plasma etching, or metal mask and plasma etching.

15. The method according to claim 13, wherein the graphene layer is disposed on the corrugated and/or stepped surface of the substrate by polymer stamping or chemical vapour deposition (CVD).
